(19) United States
(12) Patent Application Publication
(10) Pub. No.: US 2002/0113301 A1
(43) Pub. Date: Aug. 22, 2002

(54) Leadless semiconductor package

(76) Inventor: Pei Ling Tai, Hsintien City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/785,300

(22) Filed: Feb. 20, 2001

(51) Int. Cl. H01L 23/02; H01L 23/28; H01L 23/48; H01L 21/44; H01L 21/50

(52) U.S. Cl. 257/678; 257/787; 257/666; 257/690; 438/106

(57) ABSTRACT

A package for semiconductor is disclosed. It comprises four major related parts: semiconductor chips, solder layer, conductive element, and encapsulation body, especially refer to a leadless DIP (dual-in-line package) or SIP (single-in-line package). The conductive elements and bonding contacts are part of the lead frame. Each of the conductive elements is composed of three connected portions, including terminal, bridging lead and bonding contact(s). A connecting bridge is made in between each two terminals. Thus all conductive elements are linked and associated to the frame of the lead frame and the master strip. Apply solder paste and attach semiconductor chip(s). Form the unit into U shape and make the upper contact(s) attaching the bonding pad(s) of semiconductor(s). Re-flow the solder paste to form solid joints. Adhere tape to seal the openings in between terminals. The in-line units thus form a subassembly piece with a U-shape-like trough.

### FIELD OF THE INVENTION

The invention is related to diodes, transistors, integrated circuits and multi-chip circuits. It leads to the feasibility of developing a manufacturing method with simple process step and fully automated production line.

### BACKGROUND OF THE INVENTION

The package designed in the invention is applicable to printed circuit board with assembly process utilizing surface mount technology. A typical package used for print circuit board is illustrated in FIG. 1. However there are several disadvantages in that design due to:

1. In FIG. 1, it depicts that in application use the typical package with protrusive terminals 64 and 65. They are leadless terminals not as good as the ceramic capacitor or resistor.

2. The heat generated by the semiconductor chip 60 dissipates mainly through leads 62 and 63 to printed circuit board. The head dissipation capability is not high enough and improvement for this deficiency is needed.

3. The thickness of typical package is not as good as that of resistors, capacitors, transistors, and integrated circuits and multiple-chip circuits.

4. The insulation body 66 is formed by the method of transfer molding and needs a lot of sophisticated molding tooling and machines plus peripheral facilities. All the equipment are substantially expensive, therefore it leads to high manufacturing cost and the difficulties in automation.

Because of the disadvantages of the conventional packages, present invention provides improvement to the discrepancy.

### SUMMARY OF THE INVENTION

A package for semiconductor is disclosed. It comprises four major related parts: semiconductor chips, solder layer, conductive element, and encapsulation body, especially refer to a leadless DIP (dual-in-line package) or SIP (single-in-line package). In-line connected lead frames are formed by stamping a reel of metal sheet. The conductive elements and bonding contacts are part of the lead frame. Each of the conductive elements is composed of three connected portions, including terminal, bridging lead and bonding contact(s) which may be made from areas A, B, and C of lead frame material. A connecting bridge is made in between each two terminals. Thus all conductive elements are linked and associated to the frame of the lead frame and the master strip. Apply solder paste and attach semiconductor chip(s). Form the unit into U shape and make the upper contact(s) attaching the bonding pad(s) of semiconductor(s). Re-flow the solder paste to form solid joints. Adhere tape to seal the openings in between terminals. The in-line units thus form a subassembly piece with a U-shape-like trough. The sealing of the openings and the trough shape of subassemblies enable the encapsulation to be done by the method of liquid sealant filling. After encapsulation the tape is removed and the cutting street and connecting bridges are then cut off, leaving each units connected by bars to the master strip part. This configuration is advantageous to further manufacturing steps such as solder dipping of terminals, testing, inspection, marking and so forth. The finished unit is then cut off from master strip for packing.

### BRIEF DESCRIPTION OF THE DRAWING

FIG. 1 shows a cross section of semiconductor diode of conventional SMT package is illustrated in FIG. 1.

FIG. 2 and 2B show the perspective view of the present invention, wherein FIG. 2B is a detail view.

FIG. 3 shows a cross section of the package of the present invention, soldered on printed circuit board.

FIG. 4 shows a plane view of the present invention.

FIG. 5 shows the side view of the invention with solder applied and chip attached to the bonding pads of the contact.

FIG. 6 shows the cross sectional side view of the subassembly piece of the invention

FIGS. 7A to 7E show various outlines of the finished devices of the invention, wherein FIG. 7E is a detail view of FIG. 7B.

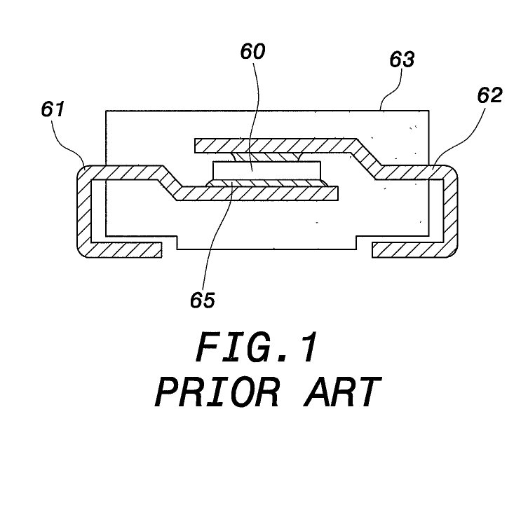

### DETAILED DESCRIPTION OF THE PREFERRED EMBODIMENT

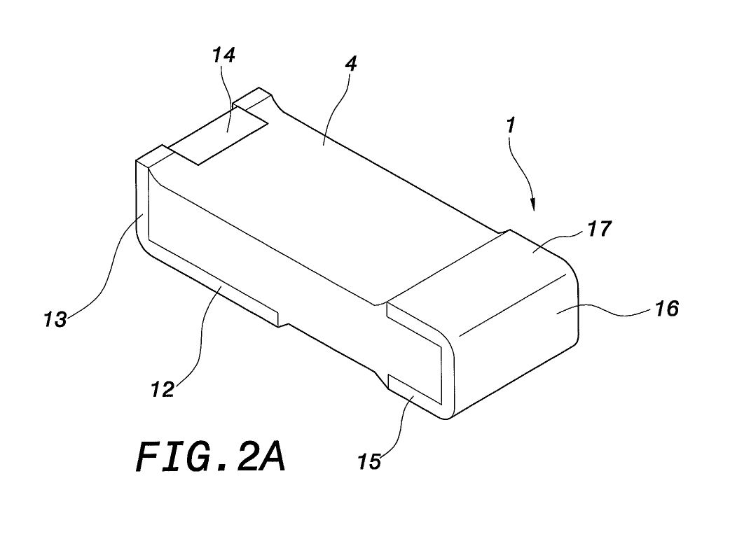

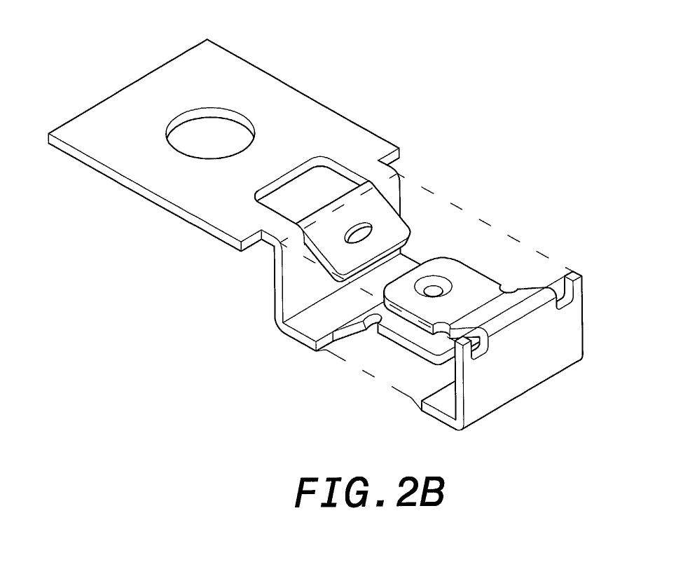

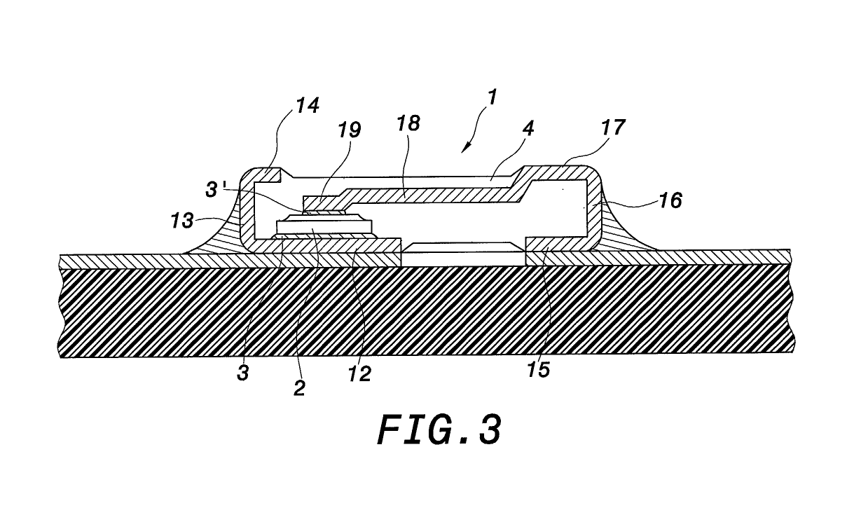

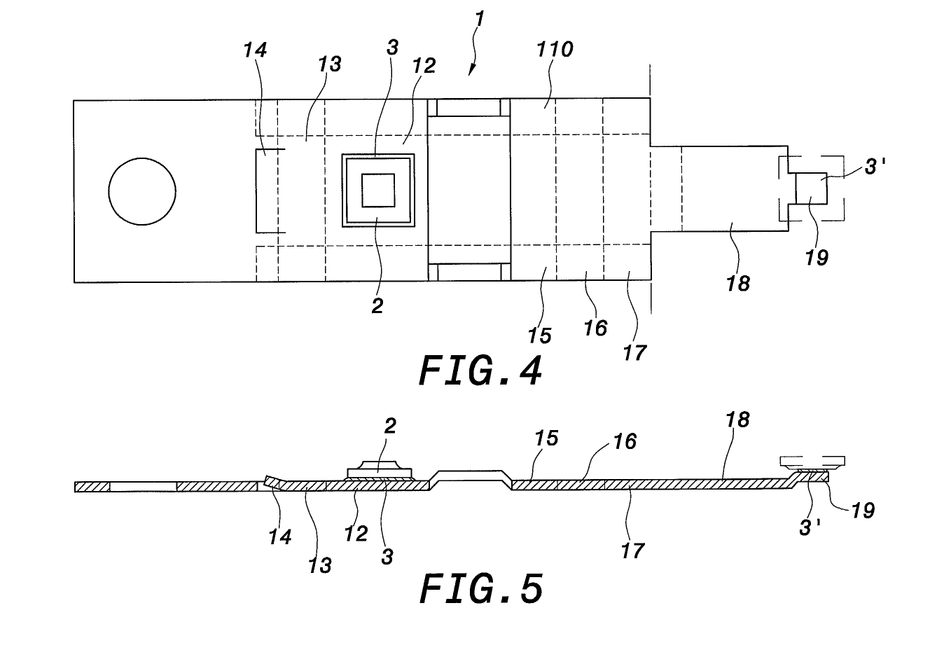

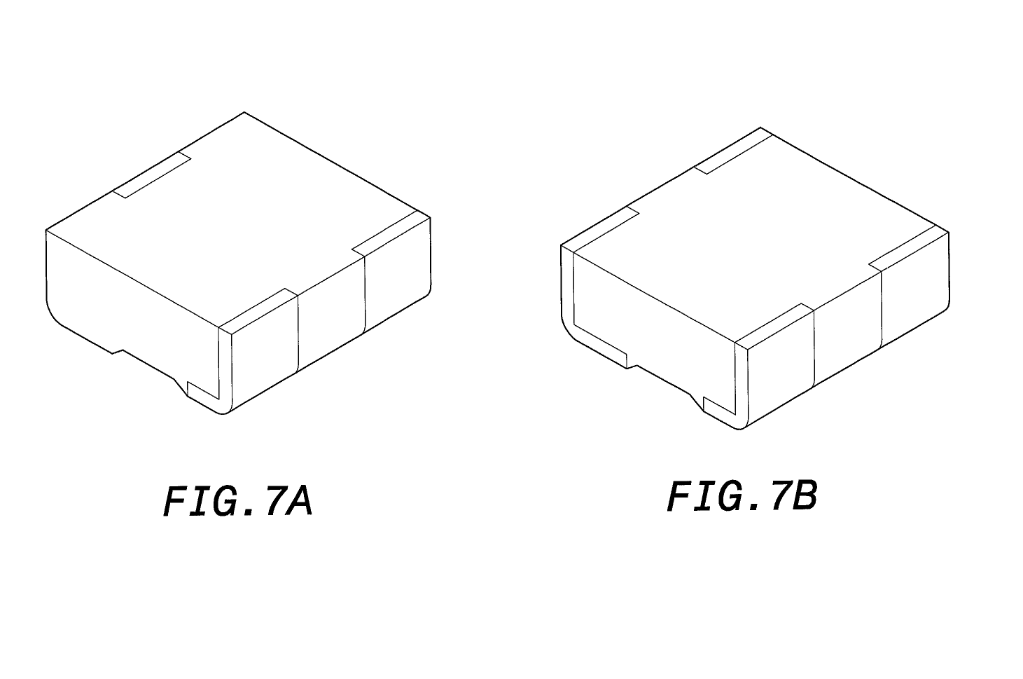

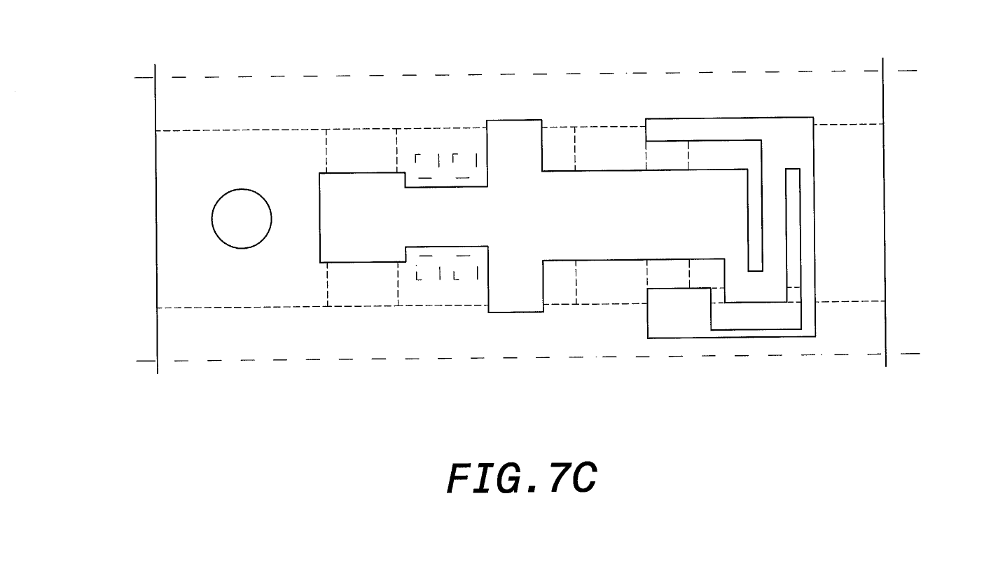

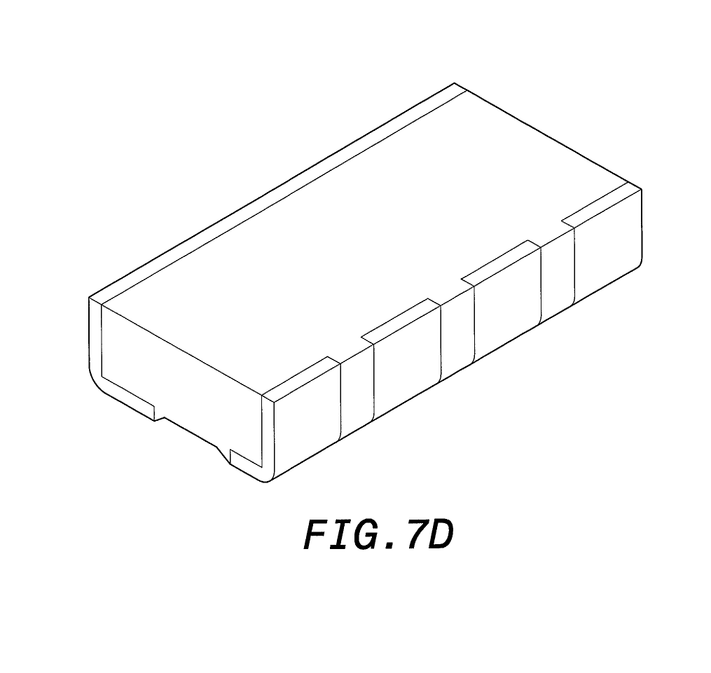

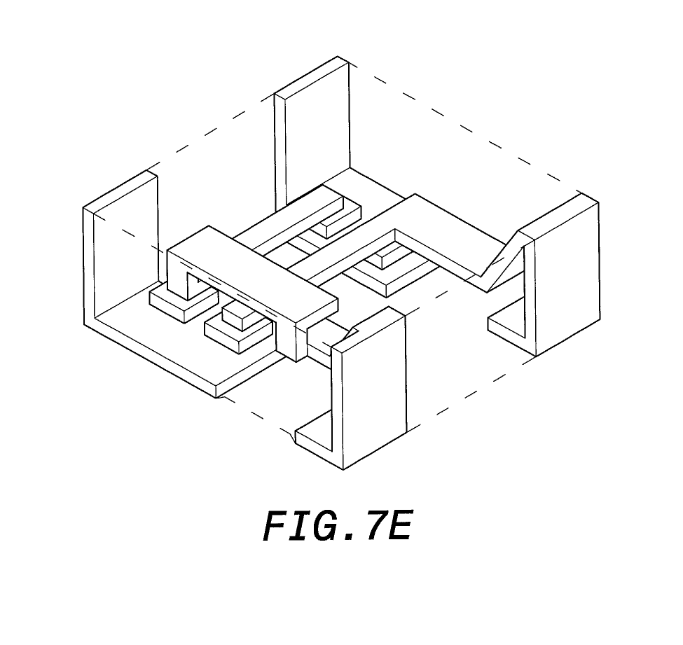

Referred to FIGS. 2, 2B, 3, 4, 5, 6, 7A˜7E, the detailed manufacturing process of the present invention is described as follows:

Step 1. Respectively apply solder paste (3)/(3′) to the chip bonding pads (12)/(19) of the contact of the conductive element (1).

Step 2. Place the semiconductor chip (2) on the solder paste (3) or on (3′).

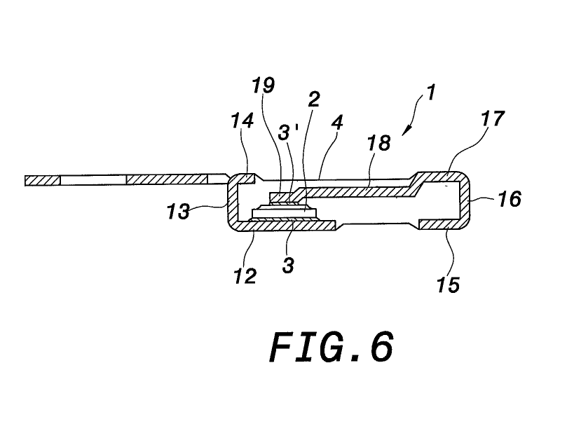

Step 3. Bend along the seven dash lines of the conductive element (1) to form individual portions including lateral terminals (right and left) (13)/(16), bottom of right terminal (15), chip bonding pads (bottom and top) (12)/(19), cutting street (110), and connecting lead (18), as shown in FIG. 6. The semiconductor chip (2) is clamped in between the chip bonding pads (12)/(19). The bending of the consecutive lead (18) as shown in FIG. 6. The semiconductor chip (2) is clamped in between the chip bonding pad (12)/(19). The bending of the consecutive conductive elements is to form the units and to simultaneously form the trough of subassembly piece to which the in-line units are connected.

Step 4 For soldering the semiconductor chip (2) in between the chip bonding pad (19) with solder (3′) and the chip bonding pad (12) with solder (3) the bonded subassembly piece is conveyed through reflow furnace with atmosphere of reduction gas.

Step 5 Attach adhesion tape to seal the openings of the trough of the subassembly piece.

FIG. 6 Fill encapsulation 4 into an opening of the subassembly piece with compound dispenser. of the subassembly piece with compound dispenser.

Step 7. Cure the liquid sealant into solid compound in curing furnace with inert gas atmosphere.

Step 8. Remove the tape.

Step 9. Cut through the cutting streets to separate the units from each other.

Step 10. Clean and dry the subassembly piece in a chemical cleaning hood.

Step 11. Hot solder dip the units to plate the terminals.

Step 12. Perform the electrical tests and other necessary inspections.

Step 13. Stamp off the unqualified units.

Step 14. Mark the units.

Step 15. Stamp off the qualified units from the master strip.

Step 16. Perform the electrical tests, which have to be conducted to individual unit.

Step 17. Pack the finished units.

From above description it is obvious that the present invention possesses the following advantages:

1. On a single piece of lead frame material, the conductive elements are made and each of them connected to the master strip, thus the subassembly piece with an array of successive units maintains its continuous in-line shape all the way through manufacturing processes, which is different from conventional lead frame design with diverse units individually processed during production.

2. Prior to the bending of the conductive elements both the bonding pads (top and the bottom) are accessible for solder paste application and semiconductor chip placement by simple automatic way.

3. Post the bending of the conductive elements and the bonding of the semiconductor chips the subassembly piece is in through-like shape with openings in the through. The sealing of adhesive tape maintains the integrity of the trough and thus the method of automatic encapsulation by injecting a proper amount of liquid sealant to he trough can be utilized. As a result, compared to the conventional epoxy molding technology, the liquid sealant encapsulation process exhibits significant benefits in manufacturing cost, production automation, and equipment simplification as well as production efficiency.

4. After the main process steps all the units are connected to the master strip it leads to high feasibility of developing full automatic production line.

Therefore, the present invention can save much worked and materials and may improve the quality. further the present invention can be produced automatically in a higher efficiency.

Although the present invention has been described with reference to the preferred embodiment, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is

1. A package for semiconductors referring as a leadless type DIP (dual-in-line package) or SIP (single-in-line package); wherein a plurality of terminals are part of a lead frame; each terminal has extended parts of internal lead(s) from either end or both ends, and semiconductor bonding contact(s) on the lead; in between terminals connecting bridge links, each two neighbor terminals, and the connected conductive element set are associated to a frame part of the lead frame; multiple lead frames are connected to the master strip forming a kind of in-line connected lead frames; after the process procedures of solder paste application, semiconductor chip attachment, lead forming, solder reflow and sealing tape adhering, the subassembly in trough form enables encapsulation to be done by continuous liquid sealant filling technique; removing the tape and cutting off the cutting streets in between neighbor units and necessary linking bars between terminals and the master strip; units finished major process steps maintain connected to master strip by linking bar(s) of non-electrical test sensitive terminal(s); the units thus are further processed by molten solder immersion plating, electrical testing, inspections, marking, singularization trimming and package.

2. The package for semiconductors as claimed in claim in claim 1, wherein the package for semiconductor is applicable to diodes, transistor, integrated circuits and multi-chip circuit.
